(19) United States
(12) Patent Application Publication
(10) Pub. No.: US 2006/0150049 A1
(43) Pub. Date: Jul. 6, 2006

(54) Method for adjusting speech volume in a telecommunications device

(75) Inventors: Zhi Zhang, Shanghai (CN); Shouhua Liu, Shanghai (CN)

Correspondence Address: PERKINS COIE LLP;PATENT-SEA, P.O. BOX 1247, SEATTLE, WA, 98111-1247, US

(73) Assignee: Spreadtrum Communications Corporation, Sunnyvale, CA (US)

(21) Appl. No.: 11/321,106

(22) Filed: Dec. 28, 2005

(30) Foreign Application Priority Data
Jan. 5, 2005 (CN) 200510023110.0

(51) Int. Cl. H04L 1/00; H03M 13/00; G08C 25/00; G06F 11/00; G06F 11/30

(52) U.S. Cl. 714/746

(57) ABSTRACT

A method of adjusting received speech volume in a handset is disclosed. The method comprises initialize a variable BFI_FACTOR as 1. Using the BFI (bad frame indicator) to determine whether a current received speech frame is erroneous or not. If the current received speech frame is not erroneous, determining if the BFI_FACTOR is less than one and if so incrementing the BFI_FACTOR. If the BFI indicates an erroneous frame, determining if the BFI_FACTOR is above a minimum value and if so decrementing the BFI_FACTOR. Finally, the current speech signal is multiplied by the BFI_FACTOR and played to the user.

### TECHNICAL FIELD OF THE INVENTION

This present invention relates to a sound volume adjusting method in a telecommunications system, and more specifically, for full-rate (FR) speech, enhanced full-rate (EFR) speech voice coding and noise cancellation in a GSM system.

### BACKGROUND OF THE INVENTION

In the GSM system, voice coding (including FR and EFR) and data reception are independent processes. Therefore, the voice codec has little information, such as interference and signal strength in the data transmission.

A voice codec typically uses a cyclic redundancy check (CRC) mechanism to determine whether a data packet is bad. Details of the CRC mechanism are well known by those who are of ordinary skill in the industry. The performance of the bad frame indicator (BFI) is a measure of effectiveness. It includes the effect of the 3-bit CRC and all other associated processing. BFI is measured by counting the number of undetected bad frames while the input signal is a randomly modulated carrier.

Additionally, as there exists a ⅛ possibility that CRC would miss and then wrongly play the bad frame, another process called error count is normally included to minimize the misjudgment of the bad frame. When an error is detected during decoding, a variable measuring the error count adds one. The error count is then compared with a predefined threshold. Whenever the variable exceeds the threshold, a determination is made that the current data packet is bad.

However, these above processes are not absolutely reliable and error-free, and there exists the possibility of not detecting a bad speech frame, which may then be decoded and played as bad speech data. This may cause uncomfortable noise and have negative effects on the mobile handset user.

Furthermore, speech decoding includes a feed-back loop to update the parameters used in the decoding process, on the basis of the information generated from the previous received data. Thus, an undetected bad data packet once being decoded may have negative impact on the subsequent decoding process. The situation may be worsened by the fact that accumulation of error decoding may further degrade sound quality and even result “speaker howling” after the noise is amplified.

### SUMMARY OF THE INVENTION

The present invention provides a speech volume adjusting method which is capable of timely adjusting the receiving speech sound. The present invention provides a receiving speech sound adjusting method capable of speech sound volume correction by multiplying a variable with the speech signal, wherein the variable value is updated during the decoding process.

The present invention provides a receiving speech sound adjusting method which is capable of reducing the negative impact on decoder parameters resulting from an undetected bad speech frame, because a variable is used to update the speech signal data in the decoding process.

### BRIEF DESCRIPTION OF THE DRAWINGS

FIG. 1 is a flow chart of the method of the present invention;

FIG. 2 shows a block diagram of the FR decoder of the present method;

FIG. 3 shows a block diagram of the EFR decoder of the present method.

### DETAILED DESCRIPTION OF THE DRAWINGS

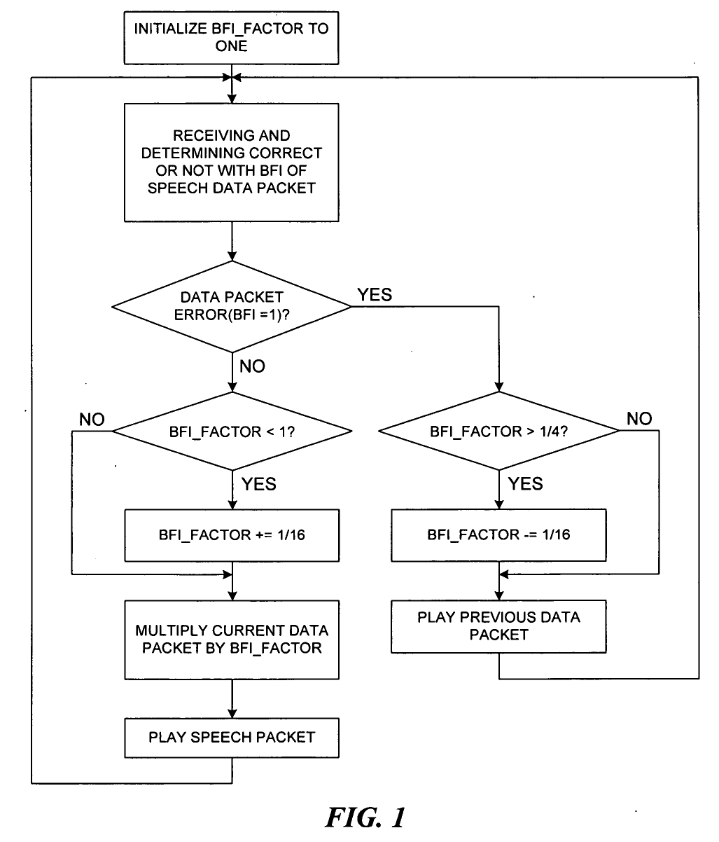

As seen in FIG. 1, a flow chart describing the method of the present invention is shown. First, at box 101, a variable (BFI_FACTOR) is initialized to 1. Then, at box 102, for the current received speech frame, the BFI is examined to determine whether the current received speech frame is in error or not. At box 103, the BFI is examined and if the BFI is one, control goes to box 108. If the BFI is not one, control goes to box 104.

At box 104, it is determined whether BFI_FACTOR is less than one. If so, control goes to box 105. Otherwise control goes to box 106.

If at box 105, an increment factor (in this specific embodiment 1/16) is added to the BFI_FACTOR variable. However, if at box 106, the current speech signal is multiplied by the BFI_FACTOR.

At box 107, the speech from the received speech frame is played for the user and control returns to box 102 for processing of the next speech frame.

At box 108, if the BFI is one from the current speech frame, a determination is made as to whether the BFI_FACTOR is greater than a minimum value. In one embodiment, the minimum value is ¼. If so, then control goes to box 109. If not, control goes to box 110.

At box 109, a decrement factor (in this embodiment 1/16) is subtracted from the BFI_FACTOR. At box 110, the speech from the received speech frame is played for the user and control returns to box 102 for processing of the next speech frame.

The described method may be implemented as hardware, software, or a combination thereof in a conventional FR or EFR decoder, so as to reduce the noise in a poor transmission situation, and enhance the user's experience.

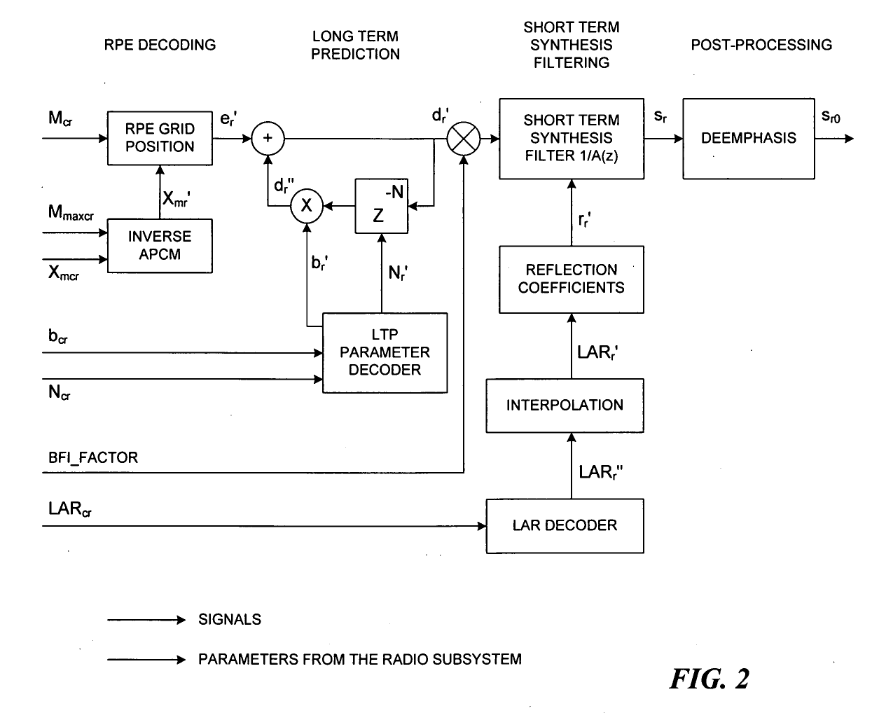

Turning next to FIG. 2, a simplified block diagram of a voice receiver in a mobile handset is shown. It is known that one purpose of the short term synthesis filtering section is to intensify the speech data frequency quality. Thus, to effectively minimize the negative influence on speech quality resulting from undetected bad speech frames, in one embodiment, the method described in the present invention should be placed prior to the operation of the short term synthesis filtering.

Furthermore, whenever a bad speech frame is detected, the BFI_FACTOR variable has 1/16 subtracted from it. Note that to avoid the situation where the received speech volume is tuned down too low to be audible, the BFI_FACTOR should never be lower than a minimum value. However, this minimum could be a different value in different situations and applications. In one embodiment, the BFI_FACTOR has a minimum value of ¼. Accordingly, if the speech frame is determined error-free, the BFI_FACTOR will be incremented by 1/16 to a maximum value of one.

In addition, it can be appreciated that the BFI_FACTOR may be initialized to different values. For example, as the to-be-decoded input data is valid in the unit of data block, which as a rule comprises of four data frames, during a mobile handset handoff process, a certain number of data frames within a data block may be received in a former cell, while the rest of the frames is received from the current serving cell. Whenever the above described situation occurs, the BFI_FACTOR can be set to a small value so as to reduce noise. In one embodiment, an initial BFI_FACTOR of 5/16 is applied when a handover or handoff occurs.

It is also appreciated that in case of sustained poor transmission, the BFI_FACTOR is at a low value. Thus, even if there is an undetected bad speech frame, the uncomfortable noise can be reduced. Additionally, the odd audio sensation which happens frequently in poor signal coverage areas can be reduced to an acceptable level as well.

The decoder depicted in FIG. 2, like the conventional FR decoder, includes the following sections:

1. RPE Decoding Section

The input signal of the long term synthesis filter (reconstruction of the long term residual signal) is formed by decoding and denormalizing the RPE-samples (APCM inverse quantization) and by placing them in the correct time position (RPE grid positioning). At this stage, the sampling frequency is increased by a factor of 3 by inserting the appropriate number of intermediate zero-valued samples.

2. Long Term Prediction Section

The reconstructed long term residual signal er′ is applied to the long term synthesis filter which produces the reconstructed short term residual signal dr′ for the short term synthesizer.

3. Short Term Synthesis Filtering Section

The coefficients of the short term synthesis filter are reconstructed applying the identical procedure to that in the encoder. The short term synthesis filter is implemented according to the lattice structure.

4. Post-Processing

The output of the synthesis filter is fed into the IIR-deemphasis filter leading to the output signal.

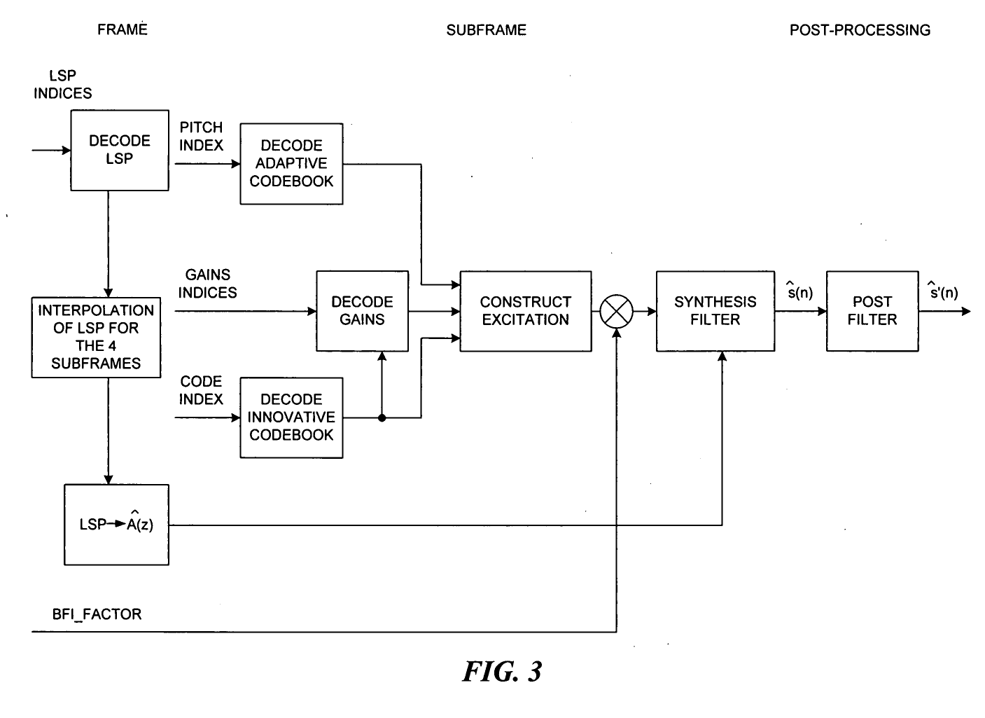

The function of the EFR decoder is shown in FIG. 3. Like conventional EFR decoders, it consists of decoding the transmitted parameters (LP parameters, adaptive codebook vector, adaptive codebook gain, fixed codebook vector, fixed codebook gain) and performing synthesis to obtain the reconstructed speech. The reconstructed speech is then post-filtered.

1. Decoding and Speech Synthesis

The decoding process is performed in the following order:

Decoding of LP filter parameters: The received indices of LSP quantization are used to reconstruct the two quantified LSP vectors. The interpolation is performed to obtain 4 interpolated LSP vectors (corresponding to 4 subframes). For each subframe, the interpolated LSP vector is converted to LP filter coefficient domain, which is used for synthesizing the reconstructed speech in the subframe.

The following steps are repeated for each subframe:

1) Decoding of the adaptive codebook vector: The received pitch index (adaptive codebook index) is used to find the integer and fractional parts of the pitch lag. The adaptive codebook vector is found by interpolating the past excitation (at the pitch delay) using the FIR filter.

2) Decoding of the adaptive codebook gain: The received index is used to readily find the quantified adaptive codebook gain, from the quantization table.

3) Decoding of the innovative codebook vector: The received algebraic codebook index is used to extract the positions and amplitudes (signs) of the excitation pulses and to find the algebraic code vector.

4) Decoding of the fixed codebook gain: The received index gives the fixed codebook gain correction factor.

5) Computing the reconstructed speech: The excitation at the input of the synthesis filter is generated at this stage.

It is to be noted that the speech volume correction method described in the present invention is in one embodiment performed after this excitation generation section, and before synthesis filtering processing.

The synthesized speech is then passed through an adaptive post filter.

2 Post-Processing

Post-processing consists of two functions: adaptive post-filtering and signal up-scaling.

While the invention has been described in the context of an embodiment, it will be apparent to those skilled in the art that the present invention may be modified in numerous ways and may assume many embodiments other than that specifically set out and described above. Accordingly, it is intended by the appended claims to cover all modifications of the invention which fall within the true spirit and scope of the invention.

What is claimed is:

1. A method of adjusting received speech volume in a handset comprising:
(a) initialize a variable BFI_FACTOR as 1;
(b) using a BFI (bad frame indicator) to determine whether a current received speech frame is erroneous or not;
(c) if the BFI equals one, going to step (h); otherwise, going to step (d);
(d) determine whether the BFI_FACTOR is less than one, and if so, going to step (e), otherwise, going to step (f);
(e) adding an increment factor to the BFI_FACTOR;
(f) multiplying a current speech signal by the BFI_FACTOR;
(g) playing the received speech data and going to step (b);
(h) determining whether the BFI_FACTOR greater than a minimum value, and if true, going to step (i), otherwise going to step (j);
(i) subtracting a decrement factor from BFI_FACTOR; and
(j) playing the received speech data and going back to step (b).

2. The method of claim 1, wherein said BFI_FACTOR initializes to 5/16 when handover occurs.

3. The method of claim 1, wherein the method may be included between the sections of long term prediction and short term synthesis filtering in FR (full rate) decoder.

4. The method of claim 1, wherein the method may be included between the two processes of excitation generation section and synthesis filtering in EFR (enhanced full rate) decoder.

5. The method of claim 1 wherein said increment factor is 1/16.

6. The method of claim 1 wherein said decrement factor is 1/16.

7. The method of claim 1 wherein said minimum value is ¼.
